(19) United States
(12) Patent Application Publication
(10) Pub. No.: US 2014/0094038 A1
(43) Pub. Date: Apr. 3, 2014

(54) ENHANCING ADHESION OF CAP LAYER FILMS

(71) Applicant: Novellus Systems, Inc., Fremont, CA (US)

(72) Inventors: Jason Dirk Haverkamp, Newberg, OR (US); Dennis Hausmann, Lake Oswego, OR (US); Roey Shaviv, Palo Alto, CA (US)

(73) Assignee: Novellus Systems, Inc., Fremont, CA (US)

(21) Appl. No.: 14/026,894

(22) Filed: Sep. 13, 2013

Related U.S. Application Data
(62) Division of application No. 11/731,581, filed on Mar. 30, 2007, now abandoned.

(51) Int. Cl. H01L 21/02

(52) U.S. Cl. CPC H01L 21/0231; H01L 21/02315
USPC 438/786; 438/778; 438/788; 438/792

(57) ABSTRACT

The present invention provides methods and apparatuses for improving adhesion of dielectric and conductive layers on a substrate to the underlying layer. The methods involve passing a process gas through a plasma generator downstream of the substrate to create reactive species. The underlying layer is then exposed to reactive species that interact with the film surface without undesirable sputtering. The gas is selected such that the interaction of the reactive species with the underlying layer modifies the surface of the layer in a manner that improves adhesion to the subsequently formed overlying layer. During exposure to the reactive species, the substrate and/or process gas may be exposed to ultraviolet radiation to enhance surface modification. In certain embodiments, a single UV cure tool is used to cure the underlying film and improve adhesion.

### CROSS REFERENCE TO RELATED APPLICATION

This application claims priority benefit as a divisional under 35 U.S.C. §119(e) to U.S. patent application Ser. No. 11/731,581, filed Mar. 30, 2007, titled “ENHANCING ADHESION OF CAP LAYER FILMS,” which us hereby incorporated by reference in its entirety.

### BACKGROUND

This invention relates to improving the interfacial adhesion of films in semiconductor processing. During integrated circuit fabrication, various films or layers are deposited to form stacks. Adhesion at the interfaces between these layers is critical for successful integration; poor adhesion of a layer to the underlying film can result in delamination at the interface when exposed to even a slight force, thereby making the film unstable or unusable in the successive integration steps or leading to eventual device failure. For example, in formation of a dual damascene structure, adhesion between dielectric layers, dielectric caps, dielectric barriers, metal and metal barriers is important.

Current technology for adhesion improvement involves plasma treatments performed in a deposition chamber, often the same chamber used to deposit the film or subsequent films. These plasma-based treatments have several problems, including dielectric constant shifts, unwanted sputtering of the film material, changes to film hydrophobicity and shifts in showerhead temperatures that can affect subsequent processing in that tool.

What is needed therefore are improved methods of increasing interfacial adhesion between layers in a stack of thin films, such as those found in an integrated circuit.

### SUMMARY OF THE INVENTION

The present invention provides methods and apparatuses for improving adhesion of dielectric and conductive layers on a substrate to an underlying layer. The methods involve passing a process gas through a plasma generator downstream of the substrate to create reactive species. The underlying layer is then exposed to reactive species that interact with the film surface without undesirable sputtering. The gas is selected such that the interaction of the reactive species with the underlying layer modifies the surface of the layer in a manner that improves adhesion to the subsequently formed overlying layer. During exposure to the reactive species, the substrate and/or process gas may be exposed to ultraviolet (UV) radiation to enhance surface modification. In certain embodiments, a single UV cure tool is used to cure the underlying film and improve adhesion.

These and other features and advantages of the present invention will be described in more detail below with reference to the associated drawings.

### BRIEF DESCRIPTION OF THE DRAWINGS

FIGS. 1A-1H show cross sectional depictions of device structures created during a dual Damascene fabrication process.

FIG. 2 is a process flow sheet showing operations in a method of improving interfacial adhesion between adjacent films in a partially fabricated integrated circuit.

FIG. 3 shows examples of interfaces in a dual Damascene device structure.

FIGS. 4 and 5 are schematic illustrations showing examples of apparatuses suitable for practicing the present invention.

### DETAILED DESCRIPTION OF THE PREFERRED EMBODIMENTS

### Introduction

In the following detailed description of the present invention, numerous specific embodiments are set forth in order to provide a thorough understanding of the invention. However, as will be apparent to those skilled in the art, the present invention may be practiced without these specific details or by using alternate elements or processes. In other instances well-known processes, procedures and components have not been described in detail so as not to unnecessarily obscure aspects of the present invention.

In this application, the terms “semiconductor wafer”, “wafer” and “partially fabricated integrated circuit” will be used interchangeably. One skilled in the art would understand that the term “partially fabricated integrated circuit” can refer to a silicon or any other appropriate semiconductor wafer during any of many stages of integrated circuit fabrication thereon. The following detailed description assumes the invention is implemented on a wafer. However, the invention is not so limited. The work piece may be of various shapes, sizes, and materials. In addition to semiconductor wafers, other work pieces that may take advantage of this invention include various articles such as printed circuit boards and the like.

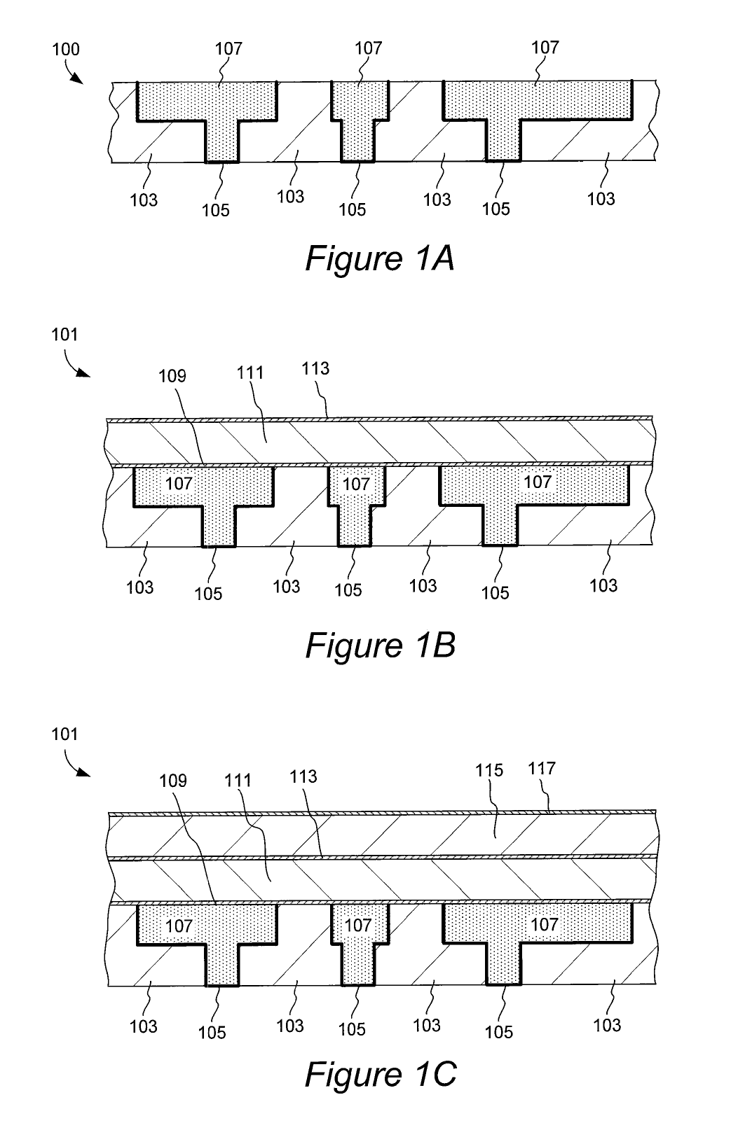

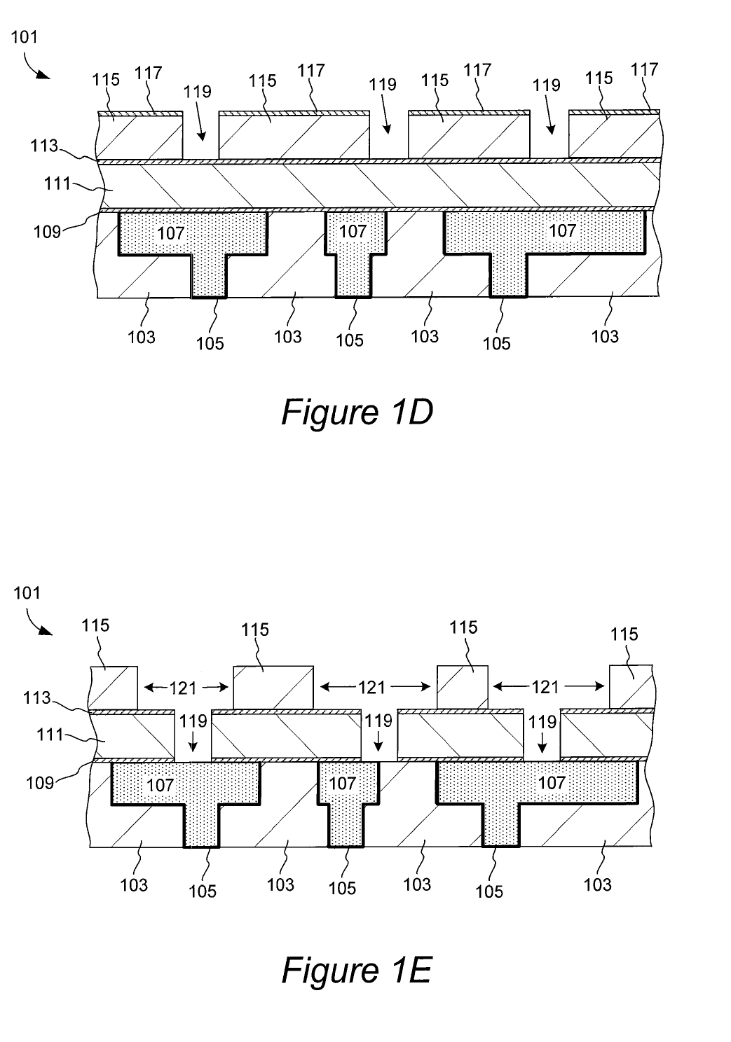

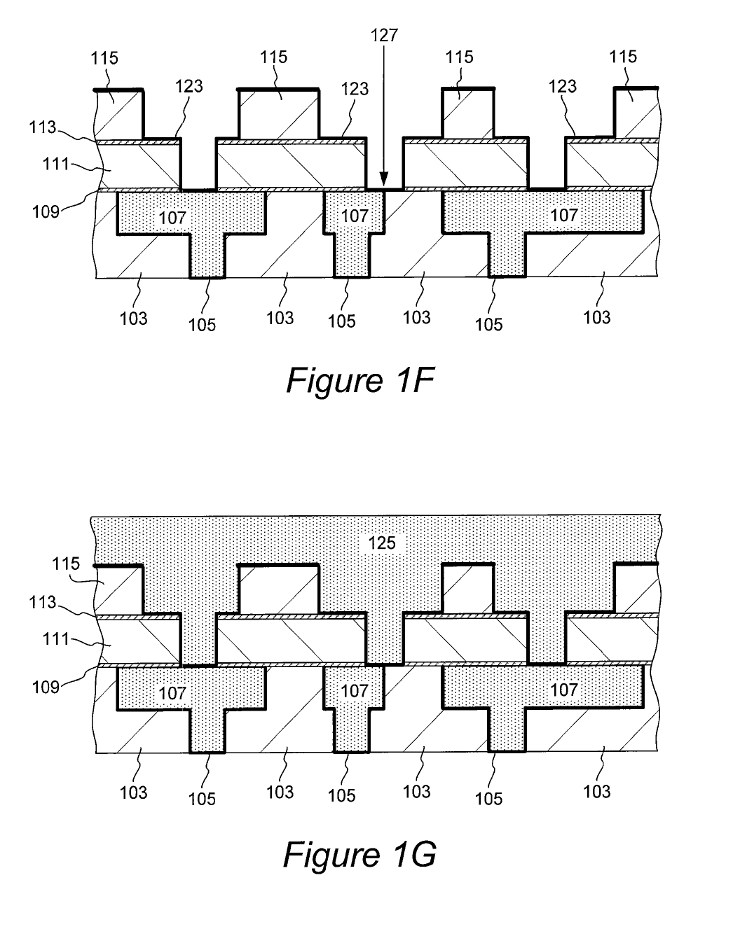

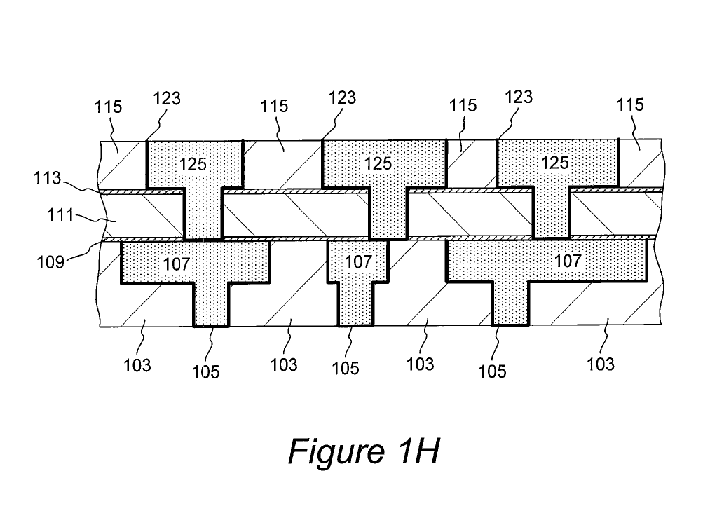

One application for the methods of the invention is in the fabrication of dual damascene devices. FIGS. 1A-1F show cross sectional depictions of device structures created at various stages of a dual Damascene fabrication process, with the cross sectional depiction of a completed structure created by the dual Damascene process is shown in FIG. 1H. Referring to FIG. 1A, an example of a typical substrate, 100, used for dual Damascene fabrication is illustrated. Substrate 100 includes a pre-formed dielectric layer 103 (such as fluorine or carbon doped silicon dioxide or organic-containing low-k materials) with etched line paths (trenches and vias) in which a diffusion barrier 105 has been deposited followed by inlaying with copper conductive routes 107. Because copper or other mobile conductive material provides the conductive paths of the integrated circuit, the underlying silicon devices must be protected from metal ions (e.g., Cu²⁺) that might otherwise diffuse or drift into the silicon. For purposes of discussion, this application may refer to copper conductive lines and seed layers; however one of skill in the art will understand that methods of the invention may be used with other types of conductive materials (e.g., aluminum).

Suitable materials for diffusion barrier 105 include tantalum, tantalum nitride, tungsten, titanium tungsten, titanium nitride, tungsten nitride, and the like. In a typical process, barrier 105 is formed by a physical vapor deposition (PVD) process such as sputtering, a chemical vapor deposition (CVD) process, or an atomic layer deposition (ALD) process. Typical metals for the conductive routes are aluminum and copper. More frequently, copper serves as the metal in Damascene processes, as depicted in these figures. The resultant partially fabricated integrated circuit 100 is a representative substrate for subsequent Damascene processing, as depicted in FIGS. 1B-1H.

As depicted in FIG. 1B, a silicon nitride or silicon carbide diffusion barrier 109 is deposited to encapsulate conductive routes 107. Next, a first dielectric layer, 111, of a dual Damascene dielectric structure is deposited on diffusion barrier 109. This is followed by deposition of an etch-stop layer 113 on the first dielectric layer 111. Typically layer 113 is a TEOS-based SiO₂ although Coral® or other low-k dielectric materials for this film may be used. In certain dual damascene schemes this “intermediate etch stop” is not used (i.e., layer 111 takes the combined thickness of layers 111 and 115 and layer 113 is no longer used).

The process follows, as depicted in FIG. 1C, where a second dielectric layer 115 of the dual Damascene dielectric structure is deposited in a similar manner to the first dielectric layer 111, onto etch-stop layer 113. Deposition of an antireflective layer 117, follows. Typically layer 117 is a TEOS-based SiO₂. Often there is an additional ARL that is mostly SiOC.

The dual Damascene process continues, as depicted in FIGS. 1D-1E, with etching of vias and trenches in the first and second dielectric layers. First, vias 119 are etched through antireflective layer 117 and the second dielectric layer 115. Standard lithography techniques are used to etch a pattern of these vias. The etching of vias 119 is controlled such that etch-stop layer 113 is not penetrated. As depicted in FIG. 1E, in a subsequent lithography process, antireflective layer 117 is removed and trenches 121 are etched in the second dielectric layer 115; vias 119 are propagated through etch-stop layer 113, first dielectric layer 111, and diffusion barrier 109.

Next, as depicted in FIG. 1F, these newly formed vias and trenches are, as described above, coated with a diffusion barrier 123. As mentioned above, barrier 123 is made of tantalum, or other materials that effectively block diffusion of copper atoms into the dielectric layers.

After diffusion barrier 123 is deposited, a seed layer of copper is deposited to enable subsequent electrofilling of the features with copper inlay 125 as shown on FIG. 1G. The blanket layer of electrodeposited copper is removed by chemical mechanical polishing (CMP) leaving the conductive material only inside the features. FIG. 1H shows the completed dual Damascene process, in which copper conductive routes 125 are inlayed (seed layer not depicted) into the via and trench surfaces over barrier 123.

Copper routes 125 and 107 are now in electrical contact and form conductive pathways, as they are separated only by diffusion barrier 123, which is also somewhat conductive.

As indicated above, the present invention relates to improving adhesion between adjacent layers, such as the various interfaces depicted in FIGS. 1A-H. Although FIGS. 1A-1H illustrate a dual Damascene process, one of skill in the art will recognize that the methods of the present invention may be used with other process flows, including single Damascene processes.

Current technology for adhesion improvement involves plasma treatments performed in a deposition chamber, often the same chamber used to deposit the film or subsequent films. These plasma-based treatments have several problems, including dielectric constant shifts, unwanted sputtering of the film material, changes to film hydrophobicity and shifts in showerhead temperatures that can affect subsequent processing in that tool.

Methods of the invention use remote or downstream plasmas to generate activated species. Dielectric and conductive films are exposed to and interact with the activated species. By appropriately selecting the process gas (based on the film properties), the interaction alters surface properties in a manner that improves adhesion between the films and subsequently deposited overlying film.

### Process

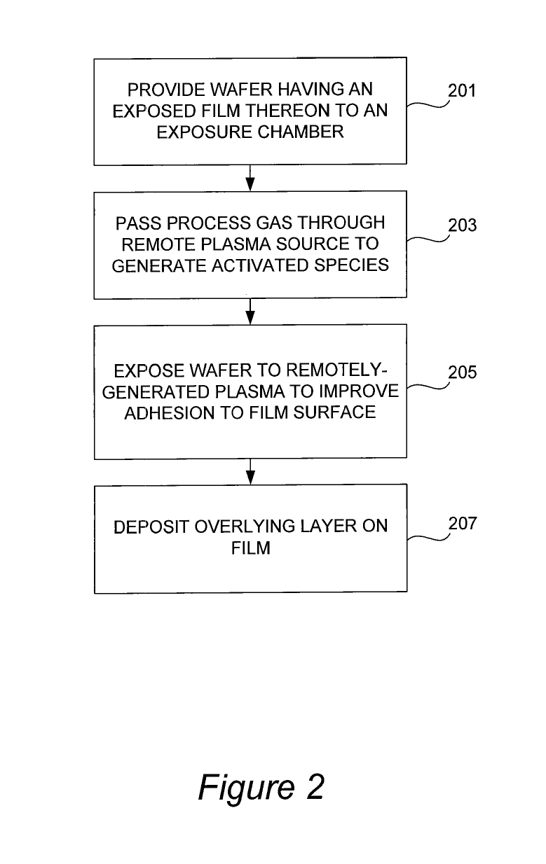

FIG. 2 is a flow chart depicting one general high-level process flow in accordance with some embodiments of the present invention. Referring to FIG. 2, a wafer with an exposed film is provided to a processing chamber (block 201). The exposed film is the lower or underlying film of the two-layer portion of the stack being formed, e.g., a diffusion barrier layer, a dielectric layer, a low-k dielectric layer, a dielectric cap layer, a metal barrier layer, or a metal layer. Specific examples of stacks (e.g., dielectric layer/dielectric cap layer) are given below. All or a portion of the film may be exposed. Providing the wafer may involve introducing it to the chamber. In some embodiments, the processing chamber is the chamber in which the previous processing step was performed (e.g., in a UV cure chamber) and the providing the wafer may involve keeping the wafer in that chamber, or transferring the wafer from one station of a multi-station chamber to another station. A process gas is passed through a plasma source remote to or downstream of the processing chamber to generate activated species (block 203). (It should be noted that the operations 201 and 203 may be performed in any appropriate order and may be performed concurrently or overlap.) The process gas may contain one gas or, in many embodiments, a combination of gases. For sake of discussion, the terms process gas or process gases may be used herein. The resulting plasma or activated species are then fed into the processing chamber. (It should be noted that the gases may not be in a plasma state for very long after leaving the remote plasma source).

One of skill in the art will recognize that the actual species present in the plasma may be a mixture of different ions, atoms and molecules derived from the process gas or gases. The activated, or highly reactive, species in the plasma source typically include ions and radicals. One of skill in the art will recognize that the activated species that exist at the plasma source will differ from the activated species that are eventually fed into the process chamber, due to recombination and reaction.

Referring again to FIG. 2, the next operation is to expose the wafer to the remotely-generated plasma a manner that improves interfacial adhesion (block 205). Exposure to the remote plasma improves interfacial adhesion by physical (e.g., roughening) and/or chemical alterations. Using a remote plasma modifies the surface without causing undesirable effects (e.g., sputtering, raising the dielectric constant, making the surface more susceptible to absorbing water). Those skilled in the art will recognize that certain process gases used may lead to undesirable effects on the exposed film. After the wafer is exposed to the remotely-generated plasma, the overlying layer is deposited (block 207). The wafer may be transferred to another chamber for deposition, may be transferred to another station of the same chamber used in the previous operation or may remain in the same chamber for deposition.

As discussed previously, plasmas that are generated within the chamber containing the wafer have been used previously to improve adhesion between two layers, but have adverse affects on the lower layer, including sputtering, change in dielectric constant, etc. The present invention improves on these methods by using a downstream or remotely-generated plasma. By exposing the film surface to a remotely-generated plasma, rather than a typical plasma that is generated within the chamber containing the wafer, surface modifications that improve adhesion without any dielectric constant shift, changes to film hydrophobicity or significant sputtering. Without being bound by a particular theory or mechanism, there are several reasons that remotely-generated plasmas are advantageous for improving interfacial adhesion. First, there is typically no electrical potential across which ions may be accelerated. Also, in certain embodiments, all or most of the ionic species in the plasma have recombined at the point that the plasma-containing gases have reached the chamber. Radical species have the necessary energy to modify the surface through chemical reactions as desired, without ion implantation or sputtering. In addition, there are no temperature shifts in a showerhead that will adversely affect subsequent processing in that tool.

In certain embodiments, UV radiation is used during the exposure operation (e.g., block 205 in FIG. 2) to enhance the number of activated species, to increase the reactivity of the existing activated species, and/or to aid the reactions at the film surface.

The plasma is typically produced by introducing the process gas or gases into the plasma chamber and exposing the mixture to conditions that form a plasma from the gas mixture. The reactive species delivered to the wafer may depend upon total flow rate of gas, type of gas, the relative amounts of gases, RF or DC power delivered to the remote plasma source, chamber pressure and substrate (wafer) size. For example, a weak oxidizing agent such as carbon dioxide will be introduced along with a carrier gas such as helium, argon or nitrogen. The carrier gas will preferably be an unreactive gas with a low breakdown voltage, although the invention is not so limited.

The wafer is typically temperature controlled during exposure to the plasma. For Damascene devices the upper limit temperature is typically around 400 degrees Celsius, although process temperature may be higher or lower depending upon the specific processes and films used in the device manufacture. Any appropriate temperature may be used, however. For example, for front end processes the temperature may be as high as about 550° C. The wafer is typically electrically grounded. In some instances, however, it may be preferable to apply a bias to the wafer or keep it floating (electrically).

### Process Gases

As mentioned previously, the methods described above find particular use in integrated circuit fabrication in which various films or layers are deposited to form stacks. The process gases are selected so that the reactive species interact with the film surface to alter the film surface properties in a manner that improves adhesion with the layer deposited in a subsequent processing operation. In certain embodiments, the reactive species improve adhesion by increasing surface area of the underlying layer. Also in certain embodiments, the reactive species may alter the stoichiometry of the surface of the underlying layer, making it more reactive.

Classes of process gases that may be used for particular films include:

1) Oxidants, which may be used, for example, to modify ultra-low k (ULK) film surfaces prior to dielectric cap or dielectric barrier layers. Examples include oxygen, carbon dioxide and peroxides;

2) F-containing compounds, which may be used, for example, to etch silicon-based films, thereby increasing film surface area and adhesion. They may also be used to create a fluorine-rich surface for adhesion improvement with fluorine-doped low-k films. Examples of suitable fluorine containing compounds include NF₃ and N₂F₆;

3) Si-containing compounds, which may be used, for example, to improve adhesion to silicon-containing films. Examples include silane (SiH₄), SiHₙ(CH₃)₄, and other organosilanes such as tetraethoxysilane (TEOS).

4) N-containing compounds, which may be used, for example, to improve adhesion when the subsequently deposited (overlying) layer is nitrogen rich, e.g., SiN or N-doped carbides. Examples include N₂, N₂/H₂ mixes, NₓO_{y} and NH₃;

5) Reducing agents, which may be used, for example, to treat metal layers by removing any oxide formation, thereby improving adhesion to the metal layer. Examples include H₂ and NH₃.

6) Noble gases such as He, Ne, Ar and Xe, which may be used, for example He can be used to enhance adhesion between dielectric films.

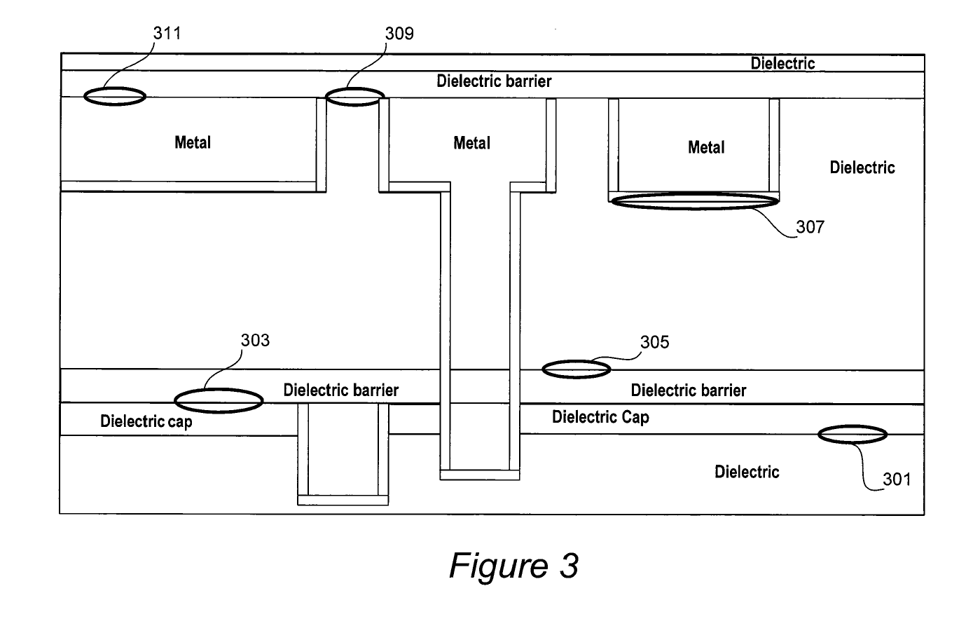

FIG. 3 shows examples of various interfaces in a typical dual Damascene structure for which the methods described herein may be used. FIG. 3 shows metal conductive routes in a dielectric material. Dielectric barrier (such as diffusion barrier 109 in FIG. 1) and metal barrier (such as diffusion barrier 123 in FIG. 1) layers are also shown. The example of a dual Damascene structure in FIG. 3 also has a dielectric cap layer located between the dielectric and dielectric barrier layers. Dielectric cap layers are used in some film stacks to encapsulate the low k dielectric, preventing reactions with chemicals during wet processing steps, and to improve etch performance. This is a hard mask that helps in avoiding line-edge roughness in etch and helps in dielectric CMP. Such hard masks are typically made out of materials such as TEOS or dense low-k materials such as HMS-CORAL.

Interface 301 is a dielectric cap layer on a dielectric layer; interface 303 is a dielectric barrier layer on a dielectric cap layer; interface 305 is a dielectric layer on a dielectric barrier; interface 307 is a metal barrier layer on a dielectric layer; interface 309 is dielectric barrier layer on a dielectric; and interface 311 is a dielectric barrier layer on metal.

Examples of materials used for typical dielectrics, dielectric barriers and dielectric caps are: SiO and SiOCH deposited from TEOS and other Si bearing precursors, fluorine doped SiO₂ and SiOCH materials, carbides (undoped and doped with nitrogen, oxygen, etc.), low dielectric constant materials (e.g., porous CDOs and spin-on organic low-k and ultra low-k dielectric materials such as SILK) and nitrides. Specific examples of dielectric layers include doped and undoped SiO and SiOCH as well as low and ultra-low dielectric constant materials such as ULK CORAL, Black Diamond, and SILK. Another example is low-k carbon doped SiO₂ (k of 1.8-3.5) of F-doped SiO₂ (k of 3.3-4.4). Specific examples of dielectric barrier layers include silicon carbides such as oxygen doped SiC (SiCO), silicon nitrides including nitrogen doped SiC (SiCN) and silicon oxides. Some integration schemes may use more than one type of barrier layer. Specific examples of dielectric cap layers include silicon oxides, which may be deposited from silane, TEOS, or similar precursors, silicon nitrides, and silicon carbides including SiO₂, SiOC (CDO), SiC, SiN, SiCO and SiCN. These materials may be doped with carbon, oxygen, or nitrogen to improve properties such as etch performance. Typical metals and metal barriers include copper, aluminum, tungsten, tungsten nitride, titanium, titanium nitride, tantalum, tantalum nitride and ruthenium. These materials are exemplary only, and the methods described herein are not limited to these but may be practiced with a wide variety of materials used in forming dielectric, dielectric cap, dielectric barrier, metal, metal barrier layers and other layers commonly used in semiconductor fabrication, including but not limited to ashable hardmasks (typically carbon-based films), anti-reflective layers, and front-end films such as high stress nitride, spacer silicon oxides, and silicides such as NiSi or CoSi.

As indicated above, the process gas may be selected based on the interface. For, example, for interfaces 301, 303, 305 and 309 (i.e., dielectric/dielectric cap/dielectric barrier layers deposited on dielectric/dielectric cap/dielectric barrier layers), typical chemistries include:
weak oxidizing compounds including carbon dioxide, carbon monoxide, methane, methanol, ethanol, isopropanol, acetone, acetic acid, nitrous oxide, nitric oxide, nitrogen dioxide and water. Stronger oxidizing compounds including peroxides may be appropriate in certain applications.
nitrogen bearing compounds including N₂, N₂O, NO₂ and NH₃
fluorine bearing compounds including CF₄, C₂F₆, C₄F₈, NF₃, N₂F₆ diluted in He
silicon bearing compounds including SiH₄, (CH₃)ₓSi₄₋ₓ, and more complicated organosilanes, such as TMCTS
   For interfaces 307 and 311 (i.e., interfaces involving metals and dielectric or dielectric barriers), typical chemistries include:
weak reducing compounds including H₂
nitrogen bearing compounds including N₂, N₂O, NO₂ and NH₃
silicon bearing compounds including SiH₄ and (CH₃)ₓSi₄₋ₓ
   Adhesion of any of the above interfaces may be improved by the methods described above. Additional examples include, but are not limited to, improving adhesion of dielectric materials such as ULK CORAL, Black Diamond, and SILK to SiC following UV cure of the SiC; adhesion of TEOS or other dielectric materials to ULK films such as ULK CORAL, Black Diamond, and SILK; adhesion of SiC to ULK following UV cure of the dielectric materials such as ULK CORAL, Black Diamond, and SILK; adhesion of SiO₂ to SiC or SiN or ULK following UV cure of the underlying film, and adhesion of metal barrier layers to dielectric materials such as ULK CORAL, Black Diamond, and SILK after etching back to the previous metal layer. ULK (i.e. ultra low-k) films include porous SiCHO films with k between 1.8 and 2.8.

### Apparatus

The present invention can be implemented in many different types of apparatus. The apparatus will include one or more chambers (sometimes referred to as process vessels) that house one or more wafers and are suitable for wafer processing. At least one chamber will be connected to a remote or downstream plasma source.

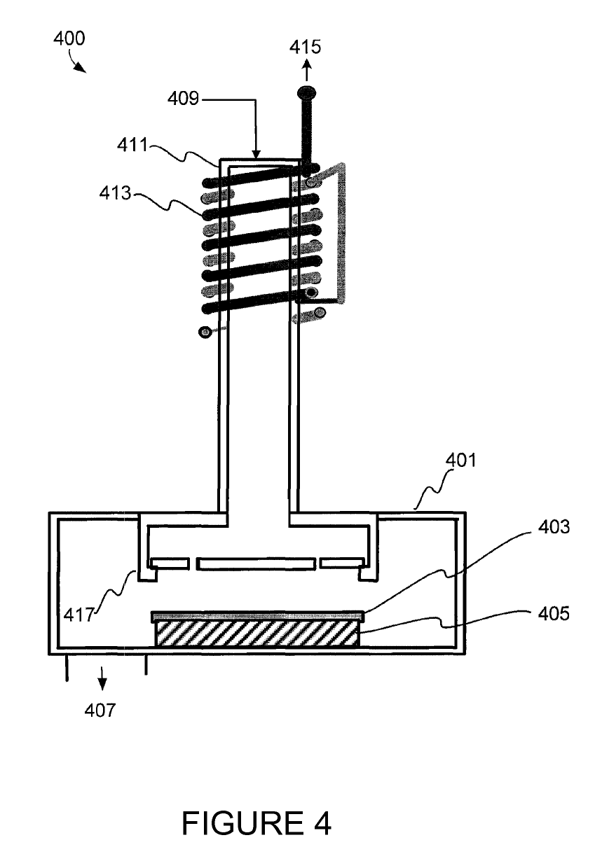

FIG. 4 is a schematic illustration showing aspects of a downstream plasma apparatus 400 suitable for practicing the present invention on wafers. Apparatus 400 has a plasma producing portion 411 and an exposure chamber 401. In the embodiment depicted in FIG. 4A, the plasma producing portion 411 and the exposure chamber 401 are separated by a showerhead assembly 417, though in other embodiments, the apparatus does not have a showerhead. Inside exposure chamber 401, a wafer 403 rests on a platen (or stage) 405. Platen 405 may be fitted with a heating/cooling element. In some embodiments, platen 405 is also configured for applying a bias to wafer 403. Low pressure is attained in exposure chamber 401 via vacuum pump via conduit 407. Sources of gas provide a flow of gas via inlet 409 into plasma producing portion 411 of the apparatus. Plasma producing portion 411 is surrounded in part by induction coils 413, which are in turn connected to a power source 415. During operation, gas mixtures are introduced into plasma producing portion 411, induction coils 413 are energized and a plasma is generated in plasma producing portion 411. In embodiments in which a showerhead assembly is used, the assembly may have an applied voltage, terminates the flow of some ions and allows the flow of neutral species into exposure chamber 401. The chamber depicted in FIG. 4 may have other features suitable for performing additional processes prior to or after the adhesion enhancement described.

In a second embodiment, the plasma is created by flowing gas through an inductively coupled source in which the plasma acts as the secondary in a transformer. An example of this type of remote plasma source is the Astron manufactured by MKS. Reactive species are produced within the plasma and are transported to a chamber which contains the wafer. The wafer is typically on a heated or cooled pedestal to control the wafer temperature.

It should be noted that any type of plasma source may be used to create the reactive species. This includes, but is not limited to, capacitively coupled plasmas, microwave plasmas, DC plasmas, and laser created plasmas.

As indicated above, in certain embodiments, UV radiation is used during the exposure operation to enhance the number and/or reactivity of the activated species in the plasma. Also in certain embodiments, the process includes UV treatment of a deposited film directly followed by an adhesion-enhancing exposure of the film to a remotely-generated plasma (i.e., without deposition or other significant processing operations in between). A single chamber may be employed for all operations of the invention or separate chambers may be used. Each chamber may house one or more wafers (substrates) for processing. The one or more chambers maintain the wafer in a defined position or positions (with or without motion within that position, e.g., rotation, vibration, or other agitation) during procedures of the invention.

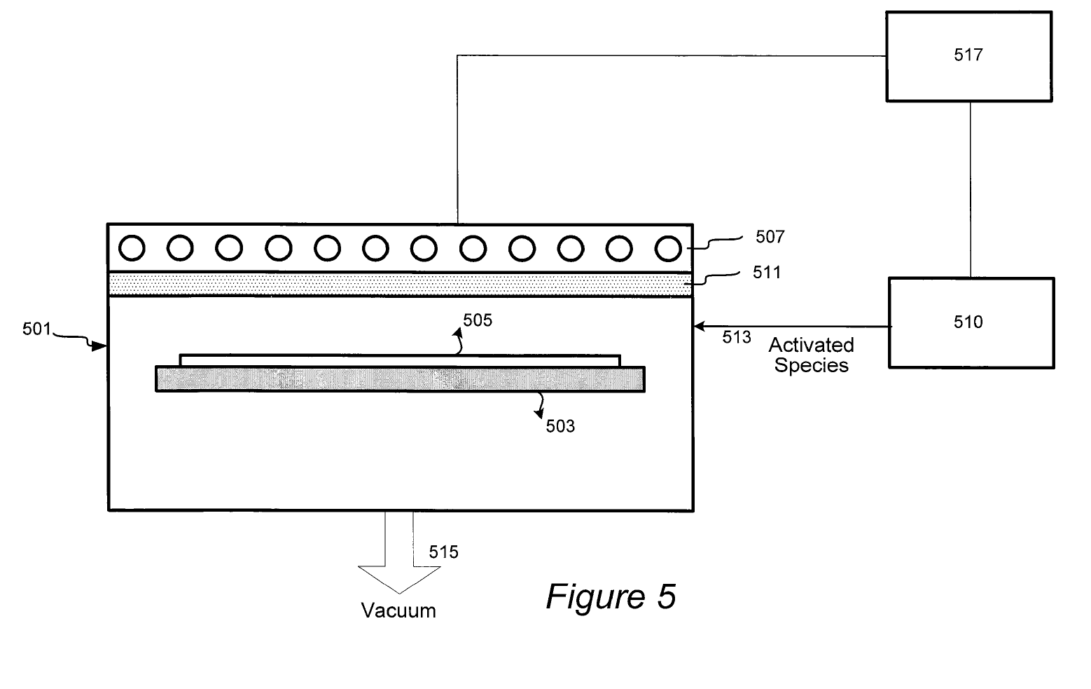

In embodiments where UV radiation is employed, the apparatus additionally has a source of UV radiation. FIG. 5 is a schematic diagram of an example chamber 501 in accordance with the invention. Chamber 501 is capable of holding a vacuum and/or containing gases at pressures above atmospheric pressure. The chamber may have one or more stations accessed in series or parallel. For simplicity, only one station is shown. In preferred embodiments, chamber 501 comprises multiple (e.g., two or more) stations, and is thus a multi-station apparatus (entire apparatus not shown). A specific preferred embodiment has four stations accessed in series. Alternatively, chamber 501 could be part of a stand-alone single station apparatus. Suitable multi-station apparatus, for example, include the modified Novellus Sequel, SOLA, and Vector systems and Applied Materials Producer systems. A suitable system may include one or more multi-station chambers.

Chamber 501 is configured with an inlet 513, which is connected to a remote plasma source 510 and allows the activated species generated in the remote plasma source 510 to enter chamber 501. For simplicity's sake, the inlet to the remote plasma source is not shown. The inlet may be at any appropriate place in the chamber. The chamber may also have another gas inlet for gases used in other processing stages, e.g., a UV cure of the wafer that may be performed prior to the adhesion enhancement. In certain embodiments, the remote plasma source may be employed in other contexts, e.g., for remote plasma cleans. Chamber 501 is also equipped with a vacuum outlet 515, which is connected to a vacuum pump (not shown). The amount of gas introduced into the chamber 501 can be controlled by valves and mass flow controller (not shown) and pressure is measured by pressure gauge (not shown).

A substrate holder 503 secures a wafer 505 in a position such that light from a UV light source-array 507 can irradiate wafer 505. Substrate holder 503 can have a heater (not shown) that can heat the substrate to defined temperatures, or could be cooled using a chiller and can be controlled by a temperature controller (not shown).

In this example, the UV light source array 507 is mounted outside the chamber 501. In alternate embodiments, the UV light source array may be housed inside the chamber 501. UV light source array 507 includes an array of individual UV sources such as mercury vapor or xenon lamps. Note that the invention is not limited to mercury vapor or xenon lamps as UV light sources and other suitable light sources include deuterium lamps or lasers (e.g., excimer lasers and tunable variations of various lasers). Various optical elements, such as reflectors, may be required to direct the UV light toward portions of the substrate. Methods for directing the light at different portions of the substrate at different times may be required as well. A scanning mechanism may be used for this purpose. A window 511 made of quartz, CaF₂, or other suitable material is positioned between UV light source array 507 and wafer 505 to provide vacuum isolation. The window material must be chosen to avoid absorption and reduce effectiveness at particular UV wavelengths. Certain high-quality quartz windows transmit UV well down to the 160-170 nm wavelength range. At shorter wavelengths, CaF₂ may be used as window material for wavelengths as short as 130 nm. Other materials with good mechanical and optical properties may also be used. Window selection will also be determined by reactivity with certain process gases. Filters can also be used to remove unwanted spectral components from particular sources to “tune” the sources.

The UV light source array 507 may be comprised of one or more types of UV sources, for example an array of three types of UV sources, each type providing UV radiation with a different wavelength distribution.

Note that the light source array and control configuration of FIG. 5 is only an example of a suitable configuration. In general, it is preferable that the lamps are arranged to provide uniform UV radiation to the wafer. For example, other suitable lamp arrangements can include circular lamps concentrically arranged or lamps of smaller length arranged at 90 degree and 180 degree angles with respect to each other may be used. The light source(s) can be fixed or movable so as to provide light in appropriate locations on the wafer. Alternatively, an optical system, including for example a series of movable lenses, filters, and/or mirrors, can be controlled to direct light from different sources to the substrate at different times.

The UV light intensity can be directly controlled by the type of light source and by the power applied to the light source or array of light sources. Factors influencing the intensity of light delivered to the wafer include, for example, the number of light sources (e.g., in an array of light sources) and the light source types (e.g., lamp type or laser type). Other methods of controlling the UV light intensity on the wafer sample include using filters that can block portions of light from reaching the wafer sample. As with the direction of light, the intensity of light at the wafer can be modulated using various optical components such as mirrors, lenses, diffusers and filters. The spectral distribution of individual sources can be controlled by the choice of sources (e.g., mercury vapor lamp vs. xenon lamp vs. deuterium lamp vs. excimer laser, etc.) as well as the use of filters that tailor the spectral distribution. In addition, the spectral distributions of some lamps can be tuned by doping the gas mixture in the lamp with particular dopants such as iron, gallium, etc.

A controller 517 is employed to control process conditions during UV treatment (or other processing) and adhesion enhancement operations, insert and remove wafers, etc. The controller will typically include one or more memory devices and one or more processors. The processor may include a CPU or computer, analog and/or digital input/output connections, stepper motor controller boards, etc.

The controller may also control all of the activities of the apparatus. The system controller executes system control software including sets of instructions for controlling the timing, mixture of gases, chamber pressure, chamber temperature, wafer temperature, RF power levels, wafer chuck or susceptor position, UV intensity and other parameters of a particular process. Other computer programs stored on memory devices associated with the controller may be employed in some embodiments.

Typically there will be a user interface associated with controller 517. The user interface may include a display screen, graphical software displays of the apparatus and/or process conditions, and user input devices such as pointing devices, keyboards, touch screens, microphones, etc.

The computer program code for controlling the UV treatment, adhesion enhancement (including generating and exposing the wafer to the downstream plasma) and other processes in a process sequence can be written in any conventional computer readable programming language: for example, assembly language, C, C++, Pascal, Fortran or others. Compiled object code or script is executed by the processor to perform the tasks identified in the program.

The controller parameters relate to process conditions such as, for example, process gas composition and flow rates, temperature, pressure, plasma source parameters such as RF power levels, cooling gas pressure, chamber wall temperature, and UV source illumination and intensity. These parameters are provided to the user in the form of a recipe, and may be entered utilizing the user interface.

Signals for monitoring the process may be provided by analog and/or digital input connections of the system controller. The signals for controlling the process are output on the analog and digital output connections of the deposition apparatus.

The system software may be designed or configured in many different ways. For example, various chamber component subroutines or control objects may be written to control operation of the chamber components necessary to carry out the inventive adhesion-enhancement processes. Examples of programs or sections of programs for this purpose include substrate positioning code, process gas control code, pressure control code, UV light source control code and plasma control code.

A substrate positioning program may include program code for controlling chamber components that are used to load the substrate onto a pedestal or chuck and to control the spacing between the substrate and other parts of the chamber such as a plasma inlet. A process gas control program may include code for controlling gas composition and flow rates. A pressure control program may include code for controlling the pressure in the chamber by regulating, e.g., a throttle valve in the exhaust system of the chamber. A plasma control program may include code for setting RF power levels applied and timing. A UV light source control program may include code for illuminating each of the UV light sources.

Examples of chamber sensors that may be monitored during the processes described above include mass flow controllers, pressure sensors such as manometers, and thermocouples located in pedestal or chuck. Appropriately programmed feedback and control algorithms may be used with data from these sensors to maintain desired process conditions.

It should be understood that the apparatus depicted in FIG. 5 is only an example of a suitable apparatus and other designs for other methods involved in previous and/or subsequent processes may be used. Examples of UV treatment apparatus that may be modified given the description above to be suitable for implementing the present invention are also described in commonly assigned co-pending application Ser. No. 11/115,576 filed Apr. 26, 2005, Ser. No. 10/800,377 filed Mar. 11, 2004 and Ser. No. 10/972,084 filed Oct. 22, 2004, incorporated by reference herein.

While the invention has been described primarily in the context of damascene processing, it is also applicable in other semiconductor processing contexts that involve forming film stacks. Examples include, but are not limited to, front-end applications, middle of the line applications, including high stress films used for straining the substrate, self aligned silicide (salicide) films, gate applications and gate spacer applications, and pre-metal dielectric such as gap spacers and high-stress nitrides, as well as aluminum interconnects and tungsten/aluminum interconnects and Ti and/or TiN thin films, and high to dielectric constant materials such as HfO and ZrO used in memory circuits. Additional applications include amorphous carbon and amorphous silicon films, anti reflective coatings, spin on dielectrics and spin on organic films (including photoresists and gap-fill materials).

Although various details have been omitted for clarity's sake, various design alternatives may be implemented. Therefore, the present examples are to be considered as illustrative and not restrictive, and the invention is not to be limited to the details given herein, but may be modified within the scope of the appended claims.

What is claimed is:

1. A method of improving adhesion to a metal or dielectric film on a partially fabricated integrated circuit comprising:
providing a partially fabricated integrated circuit having an exposed first film to a first chamber;
activating process gases via a plasma generator remote to the first chamber;
directly after exposing the first film to ultraviolet radiation, exposing the first film to activated species of process gases received from the plasma generator, wherein the activated species that the first film is exposed to include substantially no ionic species; and
forming a second film on the first film, wherein adhesion of the second film to the first film is improved by said exposure to said activated species, wherein the first and second films are dielectric films.

2. The method of claim 1 further comprising exposing the process gases to UV radiation.

3. The method of claim 2 wherein the process gas comprises at least one of a fluorine-containing compound, a silicon-containing compound, a reducing agent, a nitrogen-containing compound, and a noble gas.

4. The method of claim 1 wherein the process gas comprises a fluorine-containing compound.

5. The method of claim 1 wherein the process gas comprises a silicon-containing compound.

6. The method of claim 1 wherein the process gas comprises a reducing agent.

7. The method of claim 1 wherein the process gas comprises a nitrogen-containing compound.

8. The method of claim 1 wherein the process gas comprises a noble gas.

9. The method of claim 1 wherein the first film is a low-k dielectric film and the second film is a dielectric cap layer.

10. The method of claim 9 wherein the low-k dielectric film is a SiOCH film having a dielectric constant between 2 and 2.8 and the dielectric cap layer selected from one of silicon carbide, silicon oxide, silicon nitride, carbon doped silicon oxide, nitrogen doped silicon oxide or SiOCH.

11. The method of claim 1 wherein one of the first film and the second film is a dielectric diffusion barrier, and one of the first film and the second film is a low-k dielectric film.

12. The method of claim 11 wherein the dielectric diffusion barrier is selected from one of silicon carbide, oxygen doped silicon carbide, nitrogen doped silicon carbide, or silicon nitride and the low-k dielectric film is a SiOCH film having a dielectric constant between 2 and 2.8.

13. A method comprising:
providing a partially fabricated integrated circuit having an exposed first film to a first chamber;
activating process gases via a plasma generator remote to the first chamber;
exposing the first film to ultraviolet radiation;
directly after exposing the first film to ultraviolet radiation, exposing the first film to the activated process gases; and
forming a second film on the first film, wherein adhesion of the second film to the first film is improved by said exposure to the activated process gases, wherein the first film is a semiconductor wafer and the second film is a high stress SiN or doped SiN used to strain the semiconductor wafer.

14. A method of improving adhesion comprising:
providing a partially fabricated integrated circuit having an exposed first film to a chamber;
exposing the first film to ultraviolet radiation;
activating process gases via a remote plasma generator;
directly after exposing the first film to ultraviolet radiation, exposing the first film to the activated process gases; and
forming a second film on the first film, wherein adhesion of the second film to the first film is improved by said exposure to the activated process gases.

15. The method of claim 14 wherein exposing the first film to ultraviolet radiation and exposing the first film to activated process gases occur in the same chamber.

16. The method of claim 15 wherein the exposing the first film to ultraviolet radiation and exposing the first film to activated process gases occur in different stations of a multi-station chamber.

17. The method of claim 14 exposing the first film to the activated process gases comprises exposing the film and/or the gases to UV radiation.
